(19) United States
(12) Patent Application Publication
(10) Pub. No.: US 2009/0167391 A1
(43) Pub. Date: Jul. 2, 2009

(54) QUARTER CYCLE DELAY CLOCK GENERATOR

(76) Inventors: Dukhyo Lee, Gangnam-gu (KR); Byung-Tak Jang, Gangnam-gu (KR)

Correspondence Address: SHERR & VAUGHN, PLLC, 620 HERNDON PARKWAY, SUITE 200, HERNDON, VA, 20170, US

(21) Appl. No.: 12/344,393

(22) Filed: Dec. 26, 2008

(30) Foreign Application Priority Data
Dec. 26, 2007 (KR) 10-2007-0137005

(51) Int. Cl. H03K 5/12

(52) U.S. Cl. 327/170

(57) ABSTRACT

Embodiments relate to a quarter cycle delay clock generator. According to embodiments, a quarter cycle delay clock generator may include a reference clock generator to generate a reference clock signal, a first logic circuit to catch a first input signal input thereto at a rising edge of the reference clock signal and outputting a first input signal as a first output signal until a next rising edge of the reference clock signal, and a second logic circuit to catch a second input signal input thereto and outputting the second input signal as a second output signal. The first output signal may be inverted and input to the first logic circuit as the first input signal, and the second logic circuit may receive the first output signal from the first logic circuit as the second input signal.

The present application claims priority under 35 U.S.C. 119 to Korean Patent Application No. 10-2007-0137005 (filed on Dec. 26, 2007), which is hereby incorporated by reference in its entirety.

### BACKGROUND

Semiconductor memory devices have been improved to increase a degree of integration as well as an operation speed. For high operation speed, a synchronous memory device has been developed, which may operate in synchronism with a clock. The clock may be provided from outside of a memory chip. Among such types of memories, a single data rate (SDR) synchronous memory device may be used. A SDR synchronous memory device may operate in synchronism with a clock from outside a memory device and may input or may output data at a rising edge of a clock via each data pin. However, a SDR synchronous memory device may be insufficient to meet a speed of a system required for a high speed operation. To address such a problem, a double data rate (DDR) synchronous memory device may be used. A DDR synchronous memory may be capable of processing two data for one clock cycle. According to a DDR synchronous memory device, two data may be successively input and output via each data input/output pin in synchronism with a rising edge and a falling edge of an external clock. Therefore, a bandwidth at least twice greater than that of a SDR synchronous memory device may be realized without increasing a frequency of the clock. This may achieve a higher speed operation. To input or output data at a rising and falling edge of a clock, a clock signal generator, which may generate a clock signal delayed by a quarter cycle to have a rising and falling edge in a middle of data input or output, may be required.

Example FIG. 1 illustrates a circuit diagram of a clock signal generator. Referring to example FIG. 1, a clock signal generator may include reference clock generator 100, first logic circuit 110, second logic circuit 120, reset signal generator 130, and inverter 132. Each of first and second logic circuits 110 and 120 may output a value of its D input (data) at a moment of a rising clock edge and may not change an output value until a next rising clock edge. An example of first and second logic circuits 110 and 120 may be a D flip-flop. First logic circuit 110 may take signal FOUTB, which may be output as its output QB, as a D input. First logic circuit 110 may receive reference clock signal CLK generated from reference clock generator 100 as input CK. First logic circuit 110 may output signal FOUTB input as data input D as output Q at a rising edge of reference clock signal CLK, which may be signal FOUTi. Second logic circuit 120 may take signal FOUT90B, which may be output as its output QB, as its data input D. Second logic circuit 120 may receive reference clock signal CLK, which may be generated from reference clock generator 100 and may then be inverted by inverter 132, as its input CK. Second logic circuit 120 may then output signal FOUT90B input as data input D as its output Q at a falling edge of inverted reference clock signal CLK, which may be signal FOUT90i. Reset signal generator 130 may provide a reset signal to each of first and second logic circuits 110 and 120, which may initialize signals output as output Q of first and second logic circuits 110 and 120. Reset signals may initialize output signals FOUTi and FOUT90i to “0”. Therefore, signals output as output QB of first and second logic circuits 110 and 120 may be initialized to “1”, and thus, initial signals input as data inputs D thereof may become “1”.

Referring to example FIG. 2, a procedure in which a clock signal generator having the above-described configuration may convert reference clock signal CLK into a clock signal delayed by a quarter cycle will be described. As shown in FIG. 2, reference clock signal CLK may be generated from reference clock generator 100 and a reset signal may be produced from reset signal generator 130. Signals FOUTi and FOUT90i output as output Q of first and the second logic circuits 110 and 120 may then be initialized, i.e., become the value of “0”. At this time, reference clock signal CLK inverted by inverter 132 may be input as input CK of second logic circuit 120. Reference clock signal CLK may be input as input CK of second logic circuit 120 may be an inverted reference clock signal. In this way, as signals FOUTi and FOUT90i output as output Q of first and second logic circuits 110 and 120 may be initialized in response to a reset signal, signals input as data inputs D may become a value of “1.” Then, first logic circuit 110 may output a value of “1” input as its data input D as its output Q at first rising edge R1 of reference clock signal CLK, while outputting “0” as its output QB. A value of “0” output as output QB may be then caught and output as output Q at second rising edge R2 of reference clock signal CLK. By catching and outputting a signal being input as data input D in synchronism with reference clock signal CLK, first logic circuit 110 may generate a clock signal whose cycle may be doubled in comparison with a cycle of reference clock signal CLK and may output a clock signal thus generated as output Q, which may be signal FOUTi.

Since second logic circuit 120 may take inverted reference clock signal CLK as its input CK, a signal output as its output QB may be caught and output as its output Q at a falling edge of reference clock signal CLK. Second logic circuit 120 may output a value of “1” input as its data input D as its output Q at first falling edge F1 of reference clock signal CLK, while outputting “0” as its output QB. Then, a value of “0” output as output QB may be caught and output as output Q at second falling edge F2 of reference clock signal CLK. By catching and outputting a signal being input as data input D in synchronism with a falling edge of reference clock signal CLK, second logic circuit 120 may generate a clock signal whose cycle may be doubled in comparison with a cycle of reference clock signal CLK and may output a clock signal thus generated as output Q, which may be signal FOUT90i. Here, signal FOUT90i of second logic circuit 120 may be a quarter-cycle-delayed signal FOUTi of first logic circuit 110.

As described above, a clock signal generator may generate two clock signals by using one reference clock signal, where a frequency of each of the clock signals may be half of a frequency of the reference clock signal and a phase difference of the two clock signals thus generated may be a quarter cycle thereof. However, since such a clock signal generator may necessarily require a reset signal, it may need a separate circuit capable of generating such reset signal.

### SUMMARY

Embodiments relate to a clock generator, and further relate to a quarter cycle delay clock generator that may generate a clock signal delayed by a quarter cycle without using a reset signal.

Embodiments relate to a quarter cycle delay clock generator that may be capable of operating normally without using a separate reset signal and/or specific initial values.

According to embodiments, a quarter cycle delay clock generator may include at least one of the following. A reference clock generator to generate a reference clock signal. A first logic circuit to catch a first input signal input thereto at a rising edge of the reference clock signal and output the first input signal as a first output signal until a next rising edge of the reference clock signal, where the first output signal may be inverted and input to the first logic circuit as the first input signal. A second logic circuit to catch a second input signal input thereto and output the second input signal as a second output signal, where the second logic circuit receives the first output signal from the first logic circuit as the second input signal.

According to embodiments, a quarter cycle delay clock generator may include at least one of the following. A reference clock generator to generate a reference clock signal. A first logic circuit to catch a first input signal input thereto at a rising edge of the reference clock signal and output the first input signal as a first output signal until a next rising edge of the reference clock signal. A second logic circuit to catch a second input signal input thereto and output the second input signal as a second output signal, where the second output signal may be inverted and input to the first logic circuit as the first input signal.

According to embodiments, a quarter cycle delay clock generator may include at least one of the following. A reference clock generator to generate a reference clock signal. A first logic circuit to catch a first input signal input thereto at a rising edge of the reference clock signal and output the first input signal as a first output signal until a next rising edge of the reference clock signal. A second logic circuit to receive the first output signal from the first logic circuit as a second input signal, catching the second input signal input thereto and outputting the second input signal as a second output signal, where the second output signal may be inverted and input to the first logic circuit as the first input signal.

Embodiments may implement a quarter cycle delay clock generator by using signals produced from two logic circuits, without using a reset signal. Accordingly, embodiments may eliminate a reset signal generating circuit, which may simplify a circuit structure. Further, embodiments may use a low clock frequency, thus a circuit may be less affected by noises.

### DRAWINGS

Example FIGS. 1 and 2 illustrate a circuit diagram of a clock signal generator and a timing diagram describing an operation of the clock generator.

Example FIG. 3 illustrates a circuit diagram of a quarter cycle delay clock generator according to embodiments.

Example FIGS. 4A and 4B respectively illustrate a timing diagram describing an operation of a quarter cycle delay clock generator of example FIG. 3.

Example FIG. 5 illustrates a circuit diagram of a quarter cycle delay clock generator according to embodiments.

Example FIGS. 6A and 6B respectively illustrate a timing diagram describing an operation of a quarter cycle delay clock generator of example FIG. 5.

FIG. 7 illustrates a circuit diagram of a quarter cycle delay clock generator according to embodiments.

FIGS. 8A and 8B respectively illustrate a timing diagram describing an operation of a quarter cycle delay clock generator of example FIG. 7.

### DESCRIPTION

Example FIG. 3 illustrates a circuit diagram of a quarter cycle delay clock generator according to embodiments. Referring to example FIG. 3, a quarter cycle delay clock generator according to embodiments may include reference clock generator 300, first logic circuit 310, second logic circuit 320, and inverter 312. Each of first and second logic circuits 310 and 320 may output a value of its D input (data) at a moment of a rising clock edge and may not change an output value until a next rising clock edge. An example of first and second logic circuits 310 and 320 may be a D flip-flop. According to embodiments, first logic circuit 310 may take signal FOUTiB output as its output QB, which may be an inverted signal of a signal output as its output Q, as data input D, and may receive reference clock signal CLK generated from reference clock generator 300 as input CK. First logic circuit 310 may output signal FOUTiB input as data input D as its output Q at a rising edge of reference clock signal CLK, which may be signal FOUTi. Signal FOUTi output as output Q of first logic circuit 310 may then be input as data input D of second logic circuit 320.

According to embodiments, second logic circuit 320 may take signal FOUTi output as output Q of first logic circuit 310 as its data input D, and may receive reference clock signal CLK, which may be generated from reference clock generator 300 and inverted by inverter 312, as input CK. According to embodiments, second logic circuit 320 may output signal FOUTi input as data input D by using reference clock signal CLK. Signal output as output Q of first logic circuit 310 may be caught and output as its output Q at a falling edge of inverted reference clock signal CLK, which may be signal FOUT90i. A procedure in which a quarter cycle delay clock generator having the above-described configuration may operate without using a reset signal will be described with reference to example FIGS. 4A and 4B, according to embodiments. Referring to example FIGS. 4A and 4B, a signal output as output Q of each of first and second logic circuits 310 and 320 may be “0” or “1.” However, regardless of this, first and second logic circuits 310 and 320 may generate signals having a phase difference of a quarter cycle thereof as follows.

According to embodiments, an example where signal FOUTi output as output Q of first logic circuit 310 is “1” as depicted in example FIG. 4A will be described. Reference clock signal CLK may be generated from reference clock generator 300. Inverter 312 may invert reference clock signal CLK to input as input CK of second logic circuit 320. Reference clock signal CLK input as input CK of second logic circuit 320 may be an inverted reference clock signal. As data input D of first logic circuit 310, “0” which may be an inverted value of the signal output as output Q thereof may be input. According to embodiments, first logic circuit 310 may output a value of “0” input as data input D as output Q at first rising edge R1 of reference clock signal CLK, while outputting “1” as output QB. The value of “1” output as output QB of first logic circuit 310 may be caught and output as output Q at second rising edge R2 of reference clock signal CLK, and then input as data input D of second logic circuit 320. By catching and outputting the signal being input as data input D in synchronism with reference clock signal CLK, first logic circuit 310 may generate a clock signal whose cycle may be doubled in comparison with the cycle of reference clock signal CLK and may output a clock signal thus generated as output Q, which may be signal FOUTi.

According to embodiments, since second logic circuit 320 may take an inverted reference clock signal as its input CK, the signal input as data input D may be caught and output at a falling edge of reference clock signal CLK. Second logic circuit 320 may take signal FOUTi “0” output as output Q of first logic circuit 310, and may catch and output it as its output Q at first falling edge F1 of reference clock signal CLK. According to embodiments, a signal of “1” output as output Q of first logic circuit 310 may be caught and output at second falling edge F2 of reference clock signal CLK. By catching and outputting signal FOUTi output as output Q of first logic circuit 310 in synchronism with a falling edge of reference clock signal CLK, second logic circuit 320 may generate a clock signal whose cycle may be doubled in comparison with a cycle of reference clock signal CLK and may output the clock signal thus generated as its output Q, which may be signal FOUT90i. According to embodiments, signal FOUT90i of second logic circuit 320 may be a quarter-cycle-delayed signal FOUTi of first logic circuit 310.

According to embodiments, an example where signal FOUTi output as output Q of first logic circuit 310 is “0” as shown in example FIG. 4B will be described. Reference clock signal CLK may be generated from reference clock generator 300. Inverter 312 may invert reference clock signal CLK and may input it as input CK of second logic circuit 320. A reference clock signal input as input CK of second logic circuit 320 may be inverted reference clock signal CLK. As data input D of first logic circuit 310, “1” which may be an inverted value of the signal output as output Q thereof, may be input. According to embodiments, first logic circuit 310 may output a value of “1” input as data input D as output Q at first rising edge R1 of reference clock signal CLK, and may output “0” as output QB. A value of “0” output as output QB of first logic circuit 310 may be caught and output as output Q at second rising edge R2 of reference clock signal CLK, and may be input as data input D of second logic circuit 320. By catching and outputting the signal being input as data input D in synchronism with reference clock signal CLK, first logic circuit 310 may generate a clock signal whose cycle may be doubled in comparison with a cycle of reference clock signal CLK and may output a clock signal thus generated as output Q, which may be signal FOUTi.

According to embodiments, since second logic circuit 320 may take an inverted reference clock signal as its input CK, the signal input as data input D may be caught and output at a falling edge of reference clock signal CLK. Second logic circuit 320 may take signal FOUTi “1” output as output Q of first logic circuit 310, and may catch and output it as its output Q at first falling edge F1 of reference clock signal CLK. According to embodiments, a signal of “0” output as output Q of first logic circuit 310 may be caught and output at second falling edge F2 of reference clock signal CLK. By catching and outputting signal FOUTi output as output Q of first logic circuit 310 in synchronism with a falling edge of reference clock signal CLK, second logic circuit 320 may generate a clock signal whose cycle may be doubled in comparison with a cycle of reference clock signal CLK and may output the clock signal thus generated as its output Q, which may be signal FOUT90i. According to embodiments, signal FOUT90i of second logic circuit 320 may be a quarter-cycle-delayed signal FOUTi of first logic circuit 310.

Example FIG. 5 illustrates a circuit diagram of a quarter cycle delay clock generator according to embodiments. Referring to example FIG. 5, a quarter cycle delay clock generator according to embodiments may have a similar configuration as other embodiments set forth above. A quarter cycle delay clock generator according to embodiments may include reference clock generator 400, first logic circuit 410, second logic circuit 420, and inverter 412. First logic circuit 410 may take signal FOUT90iB output as an output QB of second logic circuit 420, which may be an inverted signal of output Q of second logic circuit 420, as its data input D, and may receive reference clock signal CLK generated from reference clock generator 400 as its input CK. First logic circuit 410 may output signal FOUT90iB input as data input D as its output Q at a rising edge of reference clock signal CLK, which may be signal FOUTi. According to embodiments, second logic circuit 420 may take signal FOUT90iB output as its output QB as data input D, which may be an inverted signal of its output Q, and may receive reference clock signal CLK, which may be generated from reference clock generator 400 and inverted by inverter 412, as its input CK. Second logic circuit 420 may output signal FOUT90iB input as data input D by using inverted reference clock signal CLK. Second logic circuit 420 may output a signal input as data input D as its output Q at a falling edge of inverted reference clock signal CLK, which may be signal FOUT90iB.

According to embodiments, a procedure in which a quarter cycle delay clock generator having the above-described configuration that may operate without using a reset signal will be described with reference to example FIGS. 6A and 6B. Referring to example FIGS. 6A and 6B, a signal output as output Q of second logic circuit 420 may be “0” or “1”. However, regardless of this, second logic circuit 420 may generate a clock signal delayed by a quarter cycle in comparison with an output signal of first logic circuit 410 as follows. According to embodiments, an example where signal FOUT90i output as output Q of second logic circuit 420 may be “0”, i.e., where signal FOUT90iB output as output QB of second logic circuit 420 may be “1”, as illustrated in example FIG. 6A, will be described. Reference clock signal CLK may be generated from reference clock generator 400. A value of “1”, which may be signal FOUT90iB output as output QB of second logic circuit 420, may be input as data input D of first logic circuit 410. First logic circuit 410 may catch and output “1” of signal FOUT90iB input as data input D as signal FOUTi at first rising edge R1 of reference clock signal CLK.

According to embodiments, second logic circuit 420 may catch and output a signal input as its data input D, i.e., signal FOUT90iB output as its output QB, as signal FOUT90i at first falling edge F1 of reference clock signal CLK. According to embodiments, the above-described procedure may be repeatedly performed. First logic circuit 410 and second logic circuit 420 may catch and output a signal at a rising edge and at a falling edge, respectively. By doing so, second logic circuit 420 may generate a clock signal whose cycle may be doubled in comparison with a cycle of reference clock signal CLK and may output a clock signal thus generated as output Q thereof, which may be signal FOUT90i. According to embodiments, signal FOUT90i of second logic circuit 420 may be a quarter-cycle-delayed signal FOUTi of first logic circuit 410.

According to embodiments, an example where signal FOUT90i output as output Q of second logic circuit 420 may be “1”, i.e., where signal FOUT90iB output as output QB of second logic circuit 420 may be “0”, as illustrated in example FIG. 6B will be described. Reference clock signal CLK may be generated from reference clock generator 400. A value of “0”, which may be signal FOUT90iB output as output QB of second logic circuit 420, may be input as data input D of first logic circuit 410. First logic circuit 410 may catch and may output “0” of signal FOUT90iB input as data input D as signal FOUTi at first rising edge R1 of reference clock signal CLK. According to embodiments, second logic circuit 420 may catch and output a signal input as its data input D, i.e., signal FOUT90iB output as its output QB, as signal FOUT90i at first falling edge F1 of reference clock signal CLK. According to embodiments, the above-described procedure may be repeatedly performed. First logic circuit 410 and second logic circuit 420 may catch and output a signal at a rising edge and at a falling edge, respectively. By doing so, second logic circuit 420 may generate a clock signal whose cycle may be doubled in comparison with a cycle of reference clock signal CLK and may output a clock signal thus generated as output Q thereof, which may be signal FOUT90i. According to embodiments, signal FOUT90i of second logic circuit 420 may be a quarter-cycle-delayed signal FOUTi of first logic circuit 410. As described herein, according to embodiments, regardless of whether “0” or “1” may be input as data input D of each of first and second logic circuits 410 and 420, two clock signals having a phase difference of a quarter cycle thereof may be generated without a reset signal, i.e., an initialization process.

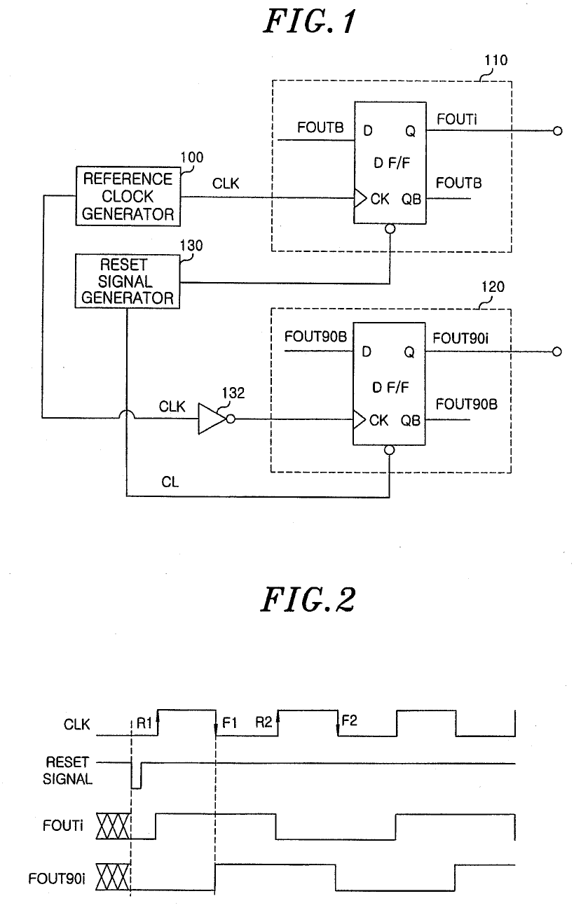

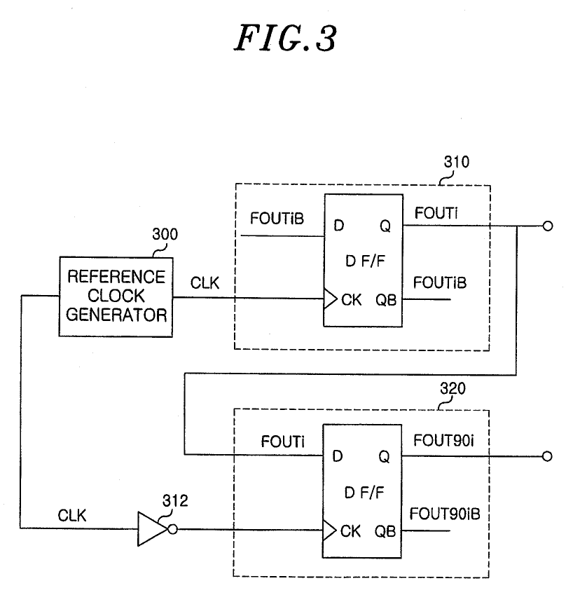

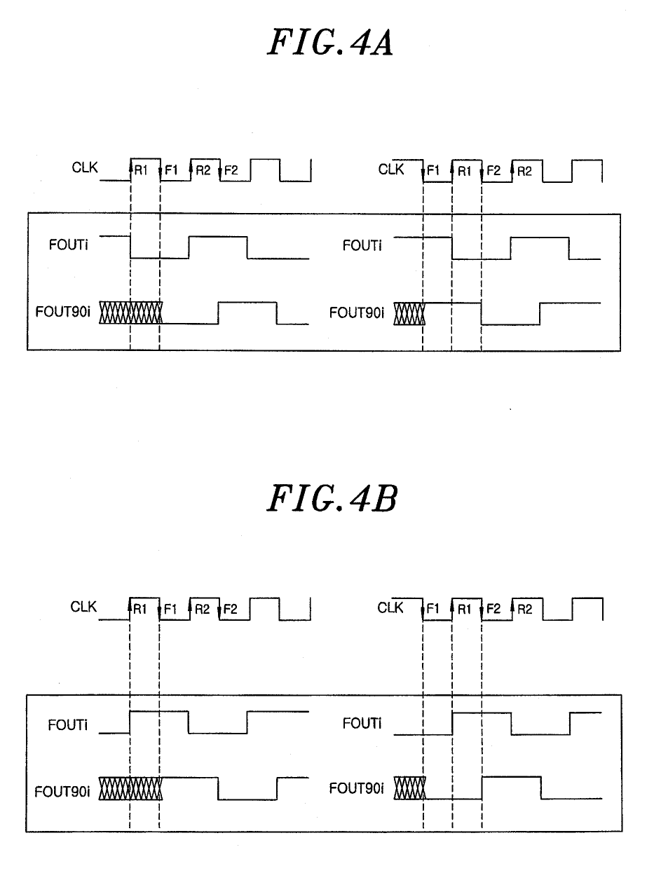

Example FIG. 7 illustrates a circuit diagram of a quarter cycle delay clock generator according to embodiments. Referring to example FIG. 7, a quarter cycle delay clock generator according to embodiments may have a similar configuration as other embodiments set forth above. A quarter cycle delay clock generator according to embodiments may include a reference clock generator 500, first logic circuit 510, second logic circuit 520, and inverter 512. According to embodiments, first logic circuit 510 may take signal FOUT90iB output as output QB of second logic circuit 520, which may be an inverted signal of output Q of second logic circuit 520, as its data input D, and may receive reference clock signal CLK generated from reference clock generator 500 as input CK. Signal FOUTi output as output Q of first logic circuit 510 may be input as data input D of second logic circuit 520. First logic circuit 510 may output signal FOUT90iB input as data input D as its output Q at a rising edge of reference clock signal CLK, which may be signal FOUTi. According to embodiments, second logic circuit 520 may take signal FOUTi output as output Q of first logic circuit 510 as its data input D, and may receive reference clock signal CLK, which may be generated from reference clock generator 500 and inverted by inverter 512, as its input CK. According to embodiments, second logic circuit 520 may output signal FOUT90i input as data input D by using an inverted reference clock signal CLK. Second logic circuit 520 may output a signal input as data input D as its output Q at a falling edge of inverted reference clock signal CLK, which may be signal FOUT90i.

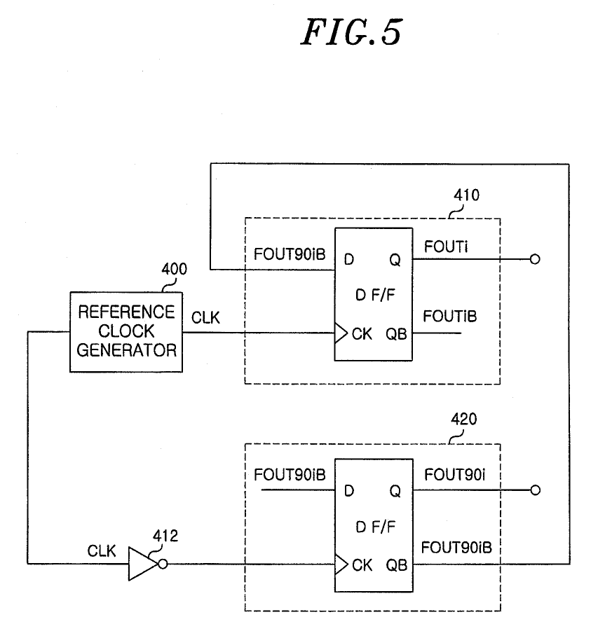

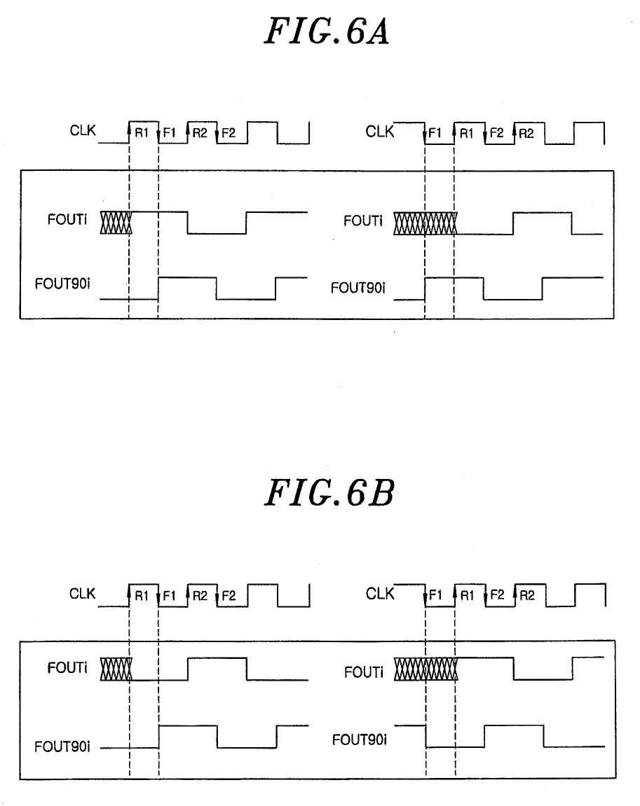

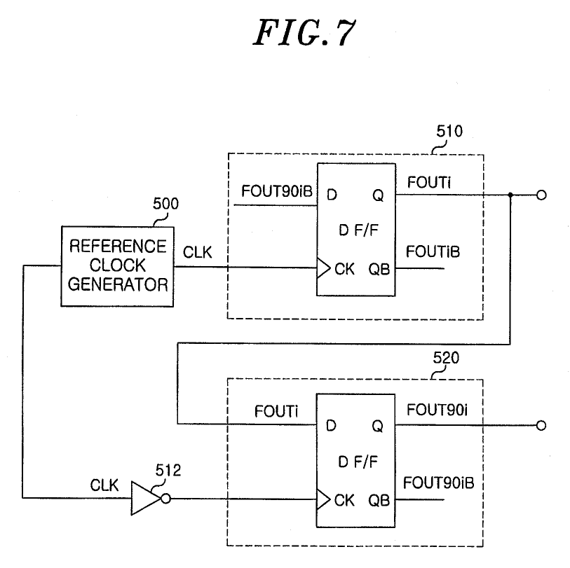

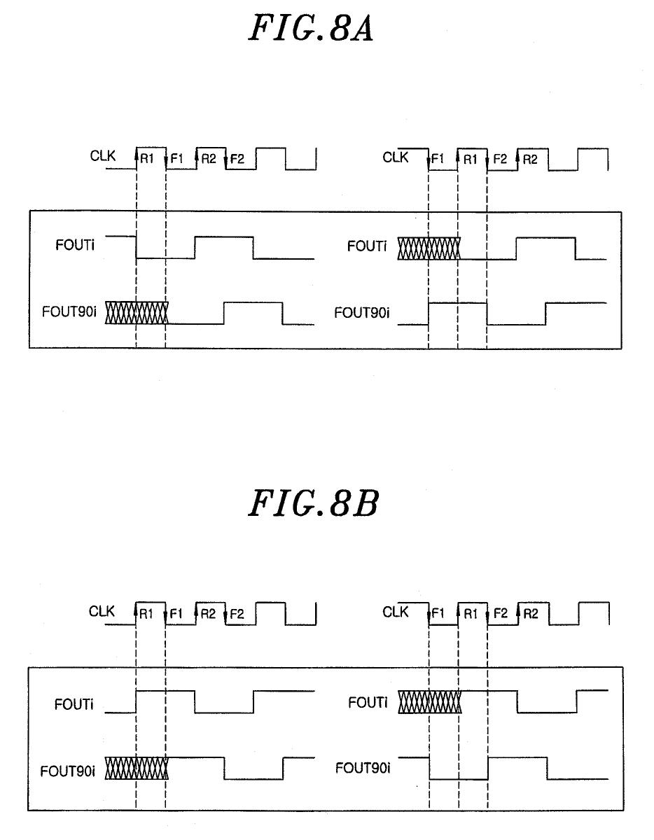

According to embodiments, a procedure in which a quarter cycle delay clock generator having the above-described configuration may operate without using a reset signal will be described with reference to example FIGS. 8A and 8B. Referring to example FIGS. 8A and 8B, a signal output as output Q of second logic circuit 520 may be “0” or “1”. However, regardless of this, second logic circuit 520 may generate a clock signal delayed by a quarter cycle in comparison with an output signal of first logic circuit 510 as follows.

According to embodiments, an example where signal FOUT90i output as output Q of second logic circuit 520 may be “1”, i.e., where signal FOUT90iB output as output QB of second logic circuit 520 may be “0”, as illustrated in example FIG. 8A will be described. Reference clock signal CLK may be generated from reference clock generator 500. A value of “0”, which may be signal FOUT90iB output as output QB of second logic circuit 520, may be input as data input D of first logic circuit 510. First logic circuit 510 may catch and output “0” of signal FOUT90iB input as data input D as signal FOUTi at first rising edge R1 of reference clock signal CLK. The signal output as output Q of first logic circuit 510 may be input as data input D of second logic circuit 520. According to embodiments, second logic circuit 520 may catch and output a signal input as its data input D, i.e., signal FOUTi output as output Q of first logic circuit 510, as signal FOUT90i at first falling edge F1 of reference clock signal CLK.

According to embodiments, the above-described procedure may be repeatedly performed. first logic circuit 510 and second logic circuit 520 may catch and output a signal at a rising edge and at a falling edge, respectively. By doing so, second logic circuit 520 may generate a clock signal whose cycle may be doubled in comparison with a cycle of reference clock signal CLK and may output a clock signal thus generated as output Q thereof, which may be signal FOUT90i. According to embodiments, signal FOUT90i of second logic circuit 520 may be a quarter-cycle-delayed signal FOUTi of first logic circuit 510. According to embodiments, an example where signal FOUT90i output as output Q of second logic circuit 520 may be “0”, i.e., where signal FOUT90iB output as output QB of second logic circuit 520 may be “1”, as illustrated in example FIG. 8B will be described. Reference clock signal CLK may be generated from reference clock generator 500 and a value of “1”, which may be signal FOUT90iB output as output QB of second logic circuit 520, may be input as data input D of first logic circuit 510. First logic circuit 510 may catch and output “1” of signal FOUT90iB input as data input D as signal FOUTi at first rising edge R1 of reference clock signal CLK. The signal output as output Q of first logic circuit 510 may be input as data input D of second logic circuit 520.

According to embodiments, second logic circuit 520 may catch and output a signal input as its data input D, i.e., signal FOUTi output as output Q of first logic circuit 510, as FOUT90i signal at first falling edge F1 of reference clock signal CLK. According to embodiments, the above-described procedure may be repeatedly performed. According to embodiments, first logic circuit 510 and second logic circuit 520 may catch and output the signal at a rising edge and at a falling edge, respectively. By doing so, second logic circuit 520 may generate a clock signal whose cycle may be doubled in comparison with a cycle of reference clock signal CLK and may output a clock signal thus generated as output Q thereof, which may be signal FOUT90i. According to embodiments, signal FOUT90i of second logic circuit 520 may be a quarter-cycle-delayed signal FOUTi of first logic circuit 510. As herein above, according to embodiments, regardless of whether “0” or “1” may be input as data input D of each of first and second logic circuits 510 and 520, two clock signals having a phase difference of a quarter cycle thereof may be generated without a reset signal, i.e., an initialization process. Meaning, a quarter cycle delay clock signal generator can be implemented without employing a circuit to generate a reset signal.

Although embodiments, have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a reference clock generator to generate a reference clock signal;
a first logic circuit to catch a first input signal input thereto at a rising edge of the reference clock signal and output the first input signal as a first output signal until a next rising edge of the reference clock signal, wherein the first output signal is inverted and input to the first logic circuit as the first input signal; and
a second logic circuit to catch a second input signal input thereto and output the second input signal as a second output signal, wherein the second logic circuit is configured to receive the first output signal from the first logic circuit as the second input signal.

2. The device of claim 1, wherein the second logic circuit is configured to catch the second input signal at a falling edge of the reference clock signal and output the second input signal as the second output signal until a next falling edge of the reference clock signal.

3. The device of claim 2, wherein the first and second logic circuits are each configured to generate an output clock signal having a cycle substantially double a cycle of the reference clock signal, and wherein the second output signal of the second logic circuit is a quarter-cycle-delayed output signal of the first output signal of the first logic circuit.

4. The device of claim 1, further comprising:
an inverter to receive the reference clock signal from the reference clock generator and invert the reference clock signal,
wherein the second logic circuit is configured to catch the second input signal at a rising edge of the inverted reference clock signal and output the second input signal as the second output signal until a next rising edge of the inverted reference clock signal.

5. The device of claim 4, wherein at least one of the first and second logic circuits is configured to generate an output clock signal having a cycle substantially double a cycle of the reference clock signal.

6. The device of claim 5, wherein the second output signal of the second logic circuit comprises a quarter-cycle-delayed output signal of the first output signal of the first logic circuit.

7. The device of claim 1, wherein the first and second logic circuits each comprise a D flip-flop.

8. A device comprising:
a reference clock generator to generate a reference clock signal;
a first logic circuit to catch a first input signal input thereto at a rising edge of the reference clock signal and output the first input signal as a first output signal until a next rising edge of the reference clock signal; and
a second logic circuit to catch a second input signal input thereto and output the second input signal as a second output signal, wherein the second output signal is inverted and input to the first logic circuit as the first input signal.

9. The device of claim 8, wherein the second logic circuit is configured to catch the second input signal input thereto at a falling edge of the reference clock signal and output the second input signal as the second output signal until a next falling edge of the reference clock signal.

10. The device of claim 9, wherein the first and second logic circuits are each configured to generate an output clock signal having a cycle substantially double a cycle of the reference clock signal, and wherein the second output signal of the second logic circuit is a quarter-cycle-delayed output signal of the first output signal of the first logic circuit.

11. The device of claim 8, further comprising:
an inverter configured to receive the reference clock signal from the reference clock generator and invert the reference clock signal,
wherein the second logic circuit is configured to catch the second input signal input thereto at a rising edge of the inverted reference clock signal and output the second input signal as the second output signal until a next rising edge of the inverted reference clock signal.

12. The device of claim 11, wherein at least one of the first and second logic circuits is configured to generate an output clock signal having a cycle substantially double a cycle of the reference clock signal.

13. The device of claim 12, wherein the second output signal of the second logic circuit comprises a quarter-cycle-delayed output signal of the first output signal of the first logic circuit.

14. The device of claim 8, wherein the first and second logic circuits each comprise a D flip-flop.

15. A device comprising:
a reference clock generator to generate a reference clock signal;
a first logic circuit to catch a first input signal input thereto at a rising edge of the reference clock signal and output the first input signal as a first output signal until a next rising edge of the reference clock signal; and
a second logic circuit to receive the first output signal from the first logic circuit as a second input signal, catch the second input signal input thereto, and output the second input signal as a second output signal, wherein the second output signal is inverted and input to the first logic circuit as the first input signal.

16. The device of claim 15, wherein the second logic circuit is configured to catch the second input signal input thereto at a falling edge of the reference clock signal and output the second input signal as the second output signal until a next falling edge of the reference clock signal.

17. The device of claim 15, further comprising:
an inverter configured to receive the reference clock signal from the reference clock generator and invert the reference clock signal,
wherein the second logic circuit is configured to catch the second input signal input thereto at a rising edge of the inverted reference clock signal and may output the second input signal as the second output signal until a next rising edge of the inverted reference clock signal.

18. The device of claim 17, wherein at least one of the first and second logic circuits is configured to generate an output clock signal having a cycle substantially double a cycle of the reference clock signal.

19. The device of claim 18, wherein the second output signal of the second logic circuit comprises a quarter-cycle-delayed output signal of the first output signal of the first logic circuit.

20. The device of claim 15, wherein the first and the second logic circuits each comprise a D flip-flop.
